(19) United States
(12) Patent Application Publication
(10) Pub. No.: US 2024/0276716 A1
(43) Pub. Date: Aug. 15, 2024

(54) SPLIT-GATE NON-VOLATILE MEMORY DEVICE AND FABRICATION METHOD THEREOF

(71) Applicant: HeFeChip Corporation Limited, Sai Ying Pun (HK)

(72) Inventor: Geeng-Chuan Chern, Cupertino, CA (US)

(73) Assignee: HeFeChip Corporation Limited, Sai Ying Pun (HK)

(21) Appl. No.: 18/117,478

(22) Filed: Mar. 6, 2023

(30) Foreign Application Priority Data
Feb. 14, 2023 (CN) 202310112923.5

(51) Int. Cl. H10B 41/30; H01L 29/423; H10B 41/10

(52) U.S. Cl. CPC H10B 41/30; H01L 29/42328; H10B 41/10

(57) ABSTRACT

The present invention provides a non-volatile memory and a manufacturing method for the same. In the non-volatile memory, a floating gate structure has a first sharp portion and a second sharp portion, and a corner formed by a side surface of the floating gate structure and a part of a top surface of the floating gate structure is not covered by a control gate structure. The corner is connected between the first sharp portion and one end of the second sharp portion. A tunneling dielectric layer of an erasing gate structure covers the first sharp portion, the second sharp portion, and a tip of the corner.

### BACKGROUND OF THE INVENTION

### 1. Field of the Invention

The invention relates generally to the field of semiconductor technology, and more particularly, to an improved floating-gate-based split-gate non-volatile memory (NVM) device and a fabrication method thereof.

### 2. Description of the Prior Art

Non-volatile memory (NVM) having arrays of NVM cells have been used in a variety of electronic systems and devices. U.S. Pat. No. 10,916,664 discloses split gate NVM cells with high erase efficiency by introducing sharp vertical floating gate (FG) edges underneath each erase gate (EG). However, the above-mentioned prior art suffer from program disturb problems.

### SUMMARY OF THE INVENTION

It is one object to provide an improved split-gate non-volatile memory (NVM) structure to solve the shortcomings or disadvantages of the above-mentioned prior art.

One aspect of the invention provides a non-volatile memory including a substrate; at least one shallow trench isolation structure, wherein a top surface of the shallow trench isolation structure is higher than a top surface of the substrate, and a lower portion of the shallow trench isolation structure is embedded in the substrate to define a plurality of active areas in the substrate; at least one floating gate structure, located on the substrate and comprising a first gate dielectric layer and a floating gate, wherein the floating gate has a first sharp portion and a second sharp portion, the first sharp portion and the second sharp portion are attached to two opposite sidewalls of the shallow trench isolation structure respectively, and wherein tips of the first sharp portion and the second sharp portion are higher than a top surface of the shallow trench isolation structure; at least one control gate structure, located on the floating gate structure, covering a partial area of the floating gate structure, and comprising a second gate dielectric layer and a control gate, wherein a corner is formed by one side surface of the floating gate structure and a part of a top surface of the floating gate structure is not covered by the control gate structure, the corner is connected between the first sharp portion and one end of the second sharp portion, wherein the first sharp portion and the second sharp portion are only disposed on the part of the top surface of the floating gate structure not covered by the control gate structure; at least one erase gate structure located on the substrate, wherein the erase gate structure is located on a side, which is provided with the corner, of the floating gate structure and comprises a tunneling dielectric layer and an erase gate, the tunneling dielectric layer covers the first sharp portion, the second sharp portion and a tip of the corner; and at least one word line structure, located on the substrate, wherein the word line structure is located on a side, which is away from the corner, of the floating gate structure and comprises a third gate dielectric layer and a word line.

According to some embodiments, the first sharp portion has a height ranging from 20 nm to 100 nm, and the second sharp portion has a height ranging from 20 nm to 100 nm.

According to some embodiments, a part of the tunneling dielectric layer, which is located above the source region, has a thickness greater than that of the first gate dielectric layer and that of rest of the tunneling dielectric layer that is not located directly above the source region.

According to some embodiments, the non-volatile memory further includes a protection dielectric layer on the control gate structure.

According to some embodiments, the non-volatile memory further includes at least one sidewall structure, the sidewall structure is disposed between the control gate structure and the erase gate structure, between the floating gate structure and the word line structure, between the control gate structure and the word line structure, and on a side of the word line structure which is away from the floating gate structure.

According to some embodiments, the non-volatile memory further includes at least one source region and at least one drain region, the source region and the drain region are located in the substrate, the source region is located under the erase gate structure and partially overlaps the floating gate structure, and the drain region is located on a side of the word line structure which is away from the floating gate structure, and partially overlaps the word line structure.

According to some embodiments, the non-volatile memory further includes a silicide layer, an interlayer dielectric layer, at least one metal bit line, and at least one contact. wherein the silicide layer is located on the drain region, the word line, and the erase gate, The interlayer dielectric layer is located on the substrate and covers structures on the substrate. The metal bit line is located on the interlayer dielectric layer. The contact is located in the interlayer dielectric layer. The contact is connected to the metal bit line and the drain region.

According to some embodiments, the top surface of the floating gate structure includes a flat surface and a recessed surface. The flat surface is directly under the control gate, and the recessed surface is directly under the erase gate. The recessed surface of the floating gate is lower than the flat surface of the floating gate. The first and second sharp portions protrude from the recessed surface of the floating gate directly under the erase gate and from the recessed surface of the shallow trench isolation structure adjacent to the first and second sharp portions.

According to some embodiments, the first gate dielectric layer has a thickness ranging from 5 nm to 15 nm, the second gate dielectric layer has a thickness ranging from 10 nm to 22 nm, the tunneling dielectric layer has a thickness ranging from 8 nm to 15 nm, and the third gate dielectric layer has a thickness ranging from 2 nm to 8 nm.

Another aspect of the invention provides a method for fabricating a non-volatile memory. A substrate is provided. At least one shallow trench isolation structure is formed. A top surface of the shallow trench isolation structure is higher than a top surface of the substrate, and a lower portion of the shallow trench isolation structure is embedded in the substrate to define a plurality of active areas in the substrate. At least one floating gate structure is formed on the substrate. The at least one floating gate structure comprises a first gate dielectric layer and a floating gate, wherein the floating gate has a first sharp portion and a second sharp portion, the first sharp portion and the second sharp portion are attached to two opposite sidewalls of the shallow trench isolation structure respectively, and wherein tips of the first sharp portion and the second sharp portion are higher than a top surface of the shallow trench isolation structure. At least one control gate structure is formed on the floating gate structure, covering a partial area of the floating gate structure. The at least one control gate structure comprises a second gate dielectric layer and a control gate, wherein a corner is formed by one side surface of the floating gate structure and a part of a top surface of the floating gate structure is not covered by the control gate structure, the corner is connected between the first sharp portion and one end of the second sharp portion, wherein the first sharp portion and the second sharp portion are only disposed on the part of the top surface of the floating gate structure not covered by the control gate structure. At least one erase gate structure is formed on the substrate. The erase gate structure is located on a side, which is provided with the corner, of the floating gate structure and comprises a tunneling dielectric layer and an erase gate, the tunneling dielectric layer covers the first sharp portion, the second sharp portion and a tip of the corner. At least one word line structure is formed on the substrate. The word line structure is located on a side, which is away from the corner, of the floating gate structure and comprises a third gate dielectric layer and a word line.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a layout diagram showing a portion of an array of a non-volatile memory according to an embodiment of the present invention;

FIG. 2 to FIG. 4 are cross-sectional views of the memory cell structure in FIG. 1 taken along direction A-A′, B-B′, and C-C′, respectively;

FIG. 5 to FIG. 37 are schematic, cross-sectional diagrams after each corresponding step in a manufacturing method for a non-volatile memory according to an embodiment of the present invention; and

FIG. 38 to FIG. 43 are schematic, cross-sectional diagrams after each corresponding step in a manufacturing method for a non-volatile memory according to another embodiment of the present invention.

### DETAILED DESCRIPTION

Advantages and features of embodiments may be understood more readily by reference to the following detailed description of preferred embodiments and the accompanying drawings. Embodiments may, however, be embodied in many different forms and should not be construed as being limited to those set forth herein. Rather, these embodiments are provided so that this disclosure will be thorough and complete and will fully convey exemplary implementations of embodiments to those skilled in the art, so embodiments will only be defined by the appended claims. Like reference numerals refer to like elements throughout the specification.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

The present invention discloses a floating-gate-based, split-gate non-volatile memory (NVM) cell structure with sharp vertical floating-gate (FG) edges disposed only between the floating gate and the erase gate. The sharp vertical FG edge does not extend to a region between the floating gate and the control gate. By providing such configuration, the erase efficiency can be enhanced without causing program disturb issues.

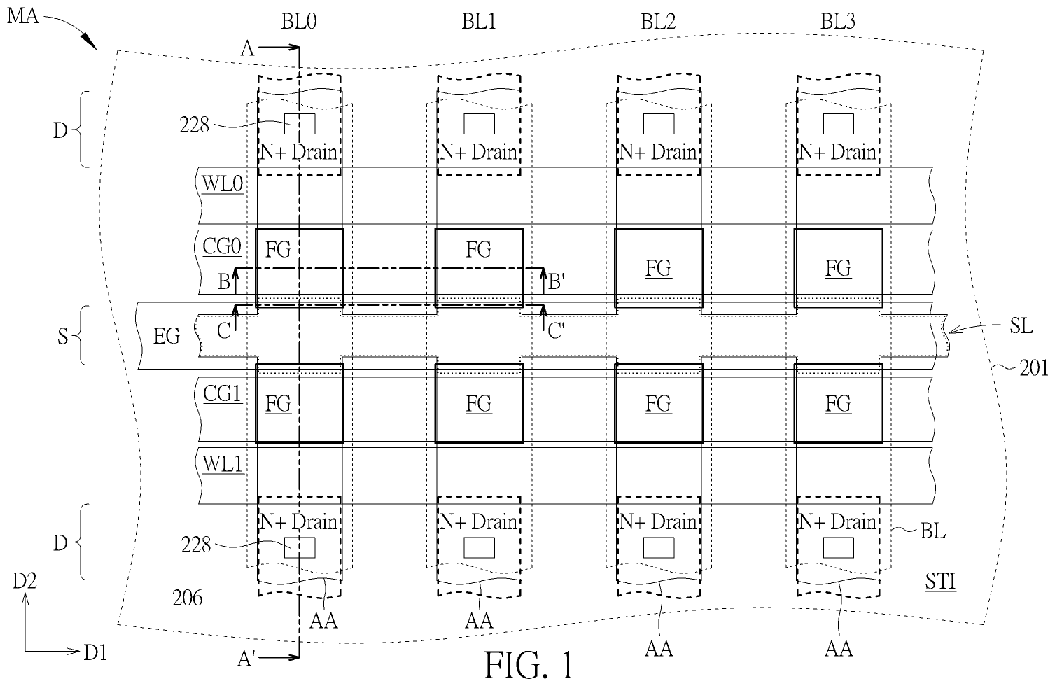

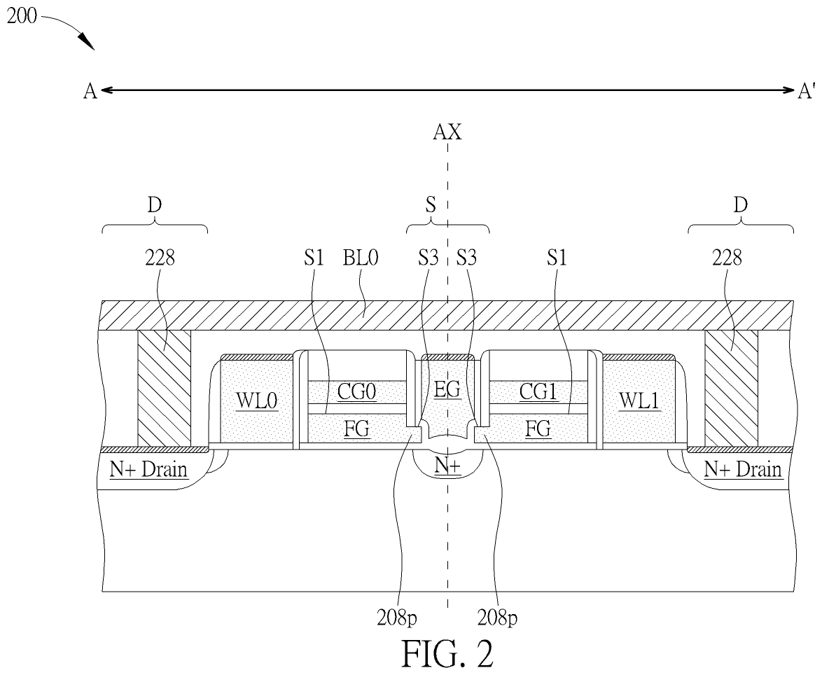

Please refer to FIG. 1 to FIG. 4. FIG. 1 is a layout diagram showing a portion of an array of a split-gate non-volatile memory according to an embodiment of the present invention. FIG. 2 to FIG. 4 are cross-sectional views of the memory cell structure in FIG. 1 taken along direction A-A′, B-B′, and C-C′, respectively. As shown in FIG. 1, the memory array MA comprises at least one word line WL, for example, word lines WL0, WL1 extending along a first direction D1, at least one control gate line CG, for example, control gate lines CG0, CGI in parallel with the at least one word line WL, at least one source line SL, at least one erase gate line EG disposed on an N⁺ source region S, at least one floating gate FG disposed under the at least one control gate line CG, at least one bit line BL, for example, bit lines BL0-BL3 extending along a second direction D2, at least one active area AA disposed on a substrate 201 and surrounded by shallow trench isolation (STI) structures 206, and at least one contact 228 disposed on an N⁺ drain region D.

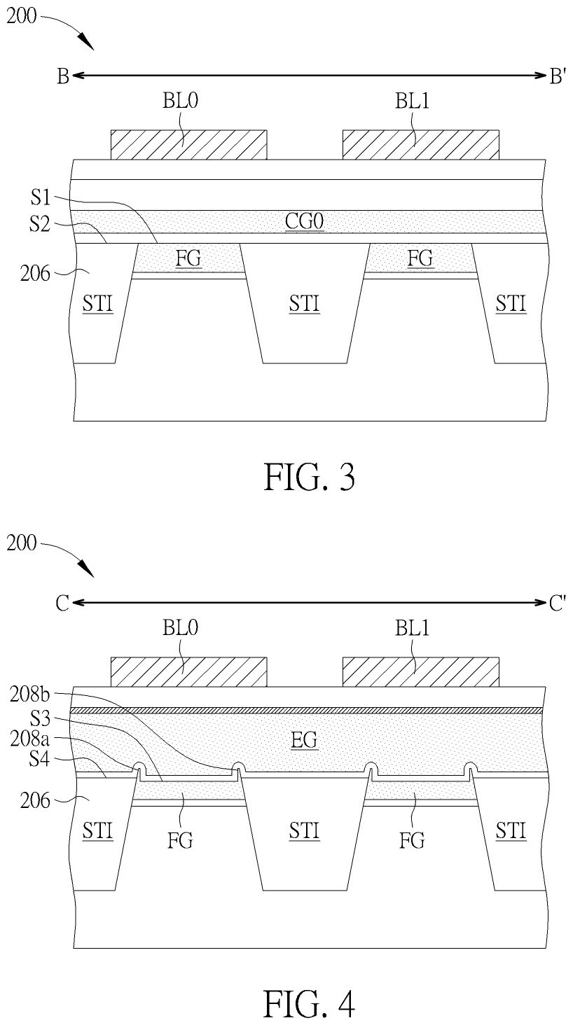

As shown in FIG. 2 and FIG. 3, the memory cell structure 200 has a mirror-symmetric structure with respect to the central axis AX. The floating gate FG has an inner lower portion 208p extending toward the erase gate EG. The floating gate FG has a first surface S1 directly under the control gate CG0. The first surface S1 is coplanar with a second surface S2 of the adjacent STI structure 206. No protrusion is formed on the first surface S1 of the floating gate FG directly under the control gate CG0. As shown in FIG. 4, the floating gate FG has a third surface S3 directly under the erase gate EG, which is lower than the first surface S1. Two opposite sharp portions 208a and 208b protrude from the third surface S3 and from a fourth surface S4 of the STI structure 206 adjacent to the sharp portions 208a and 208b.

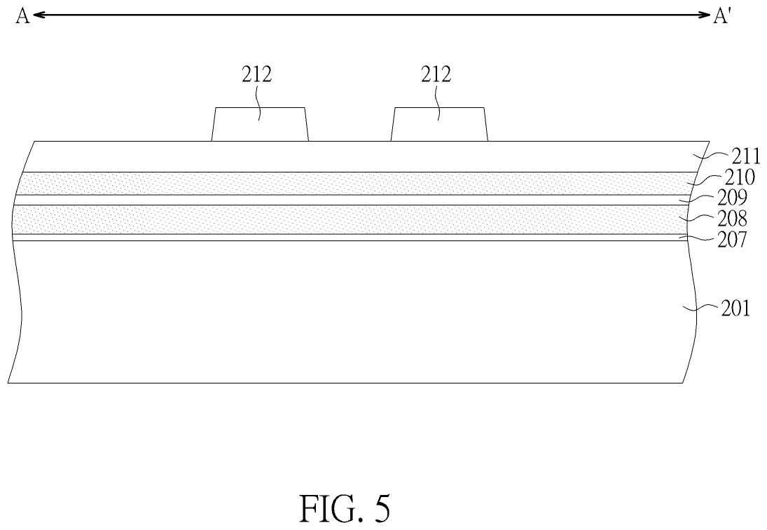

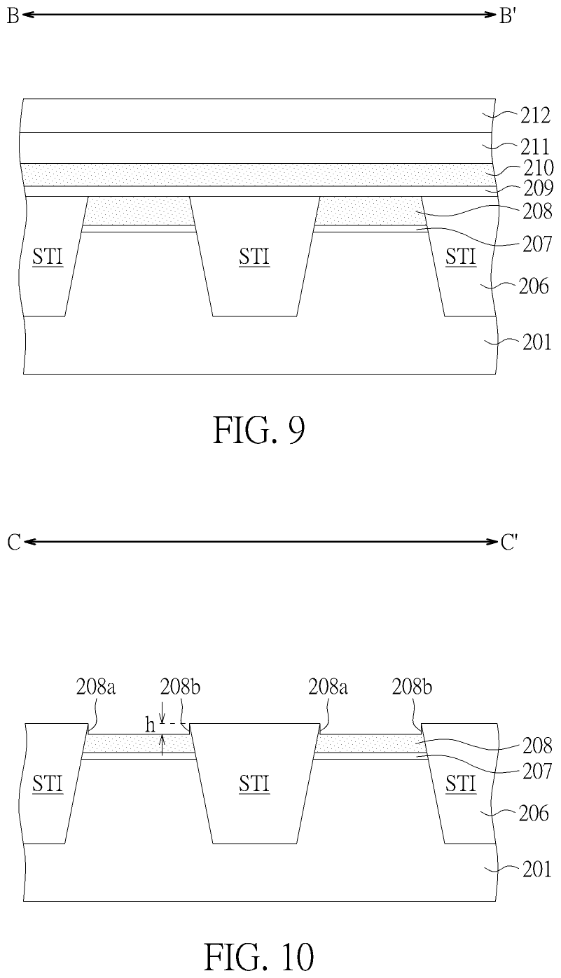

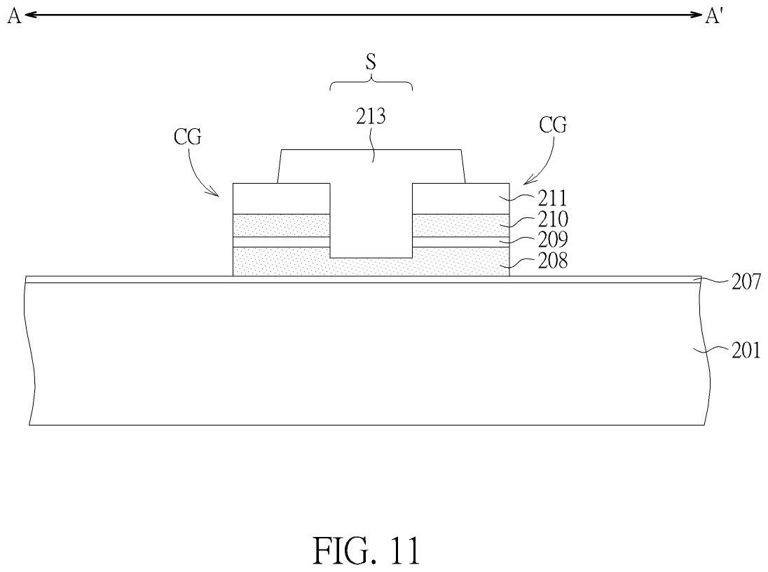

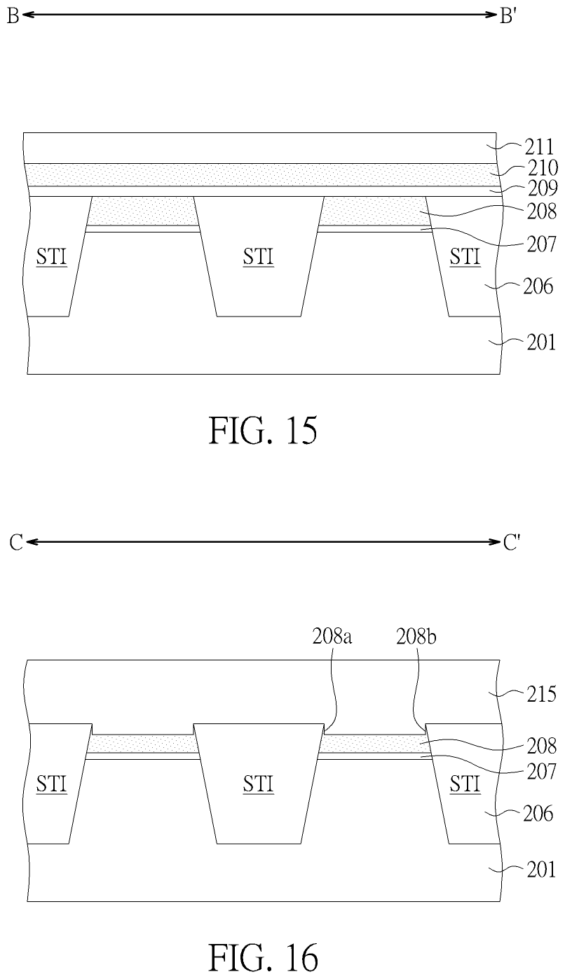

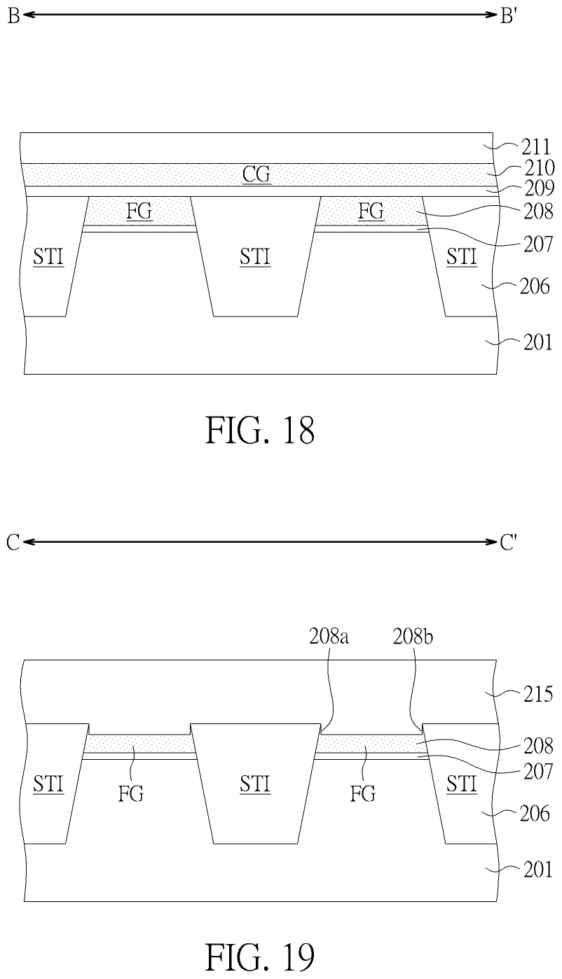

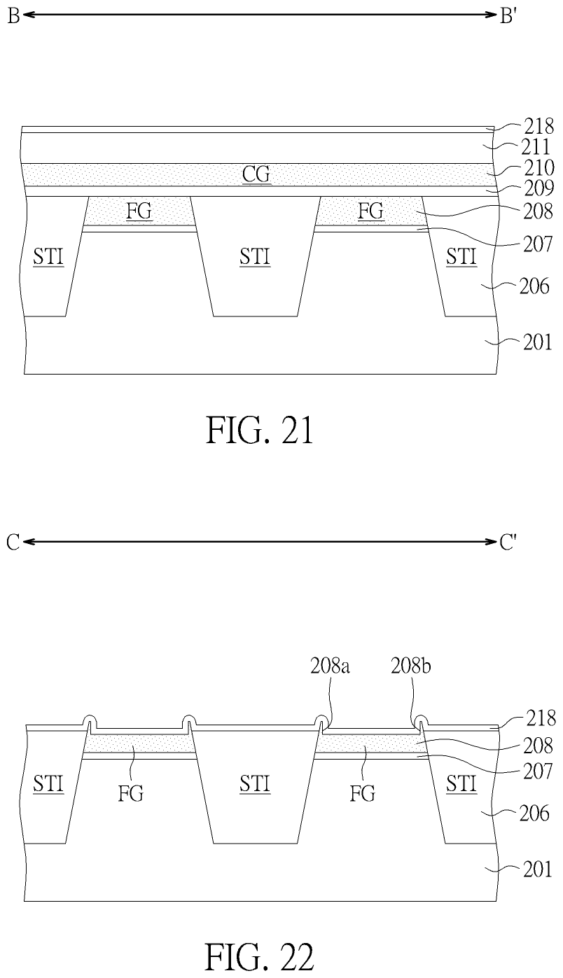

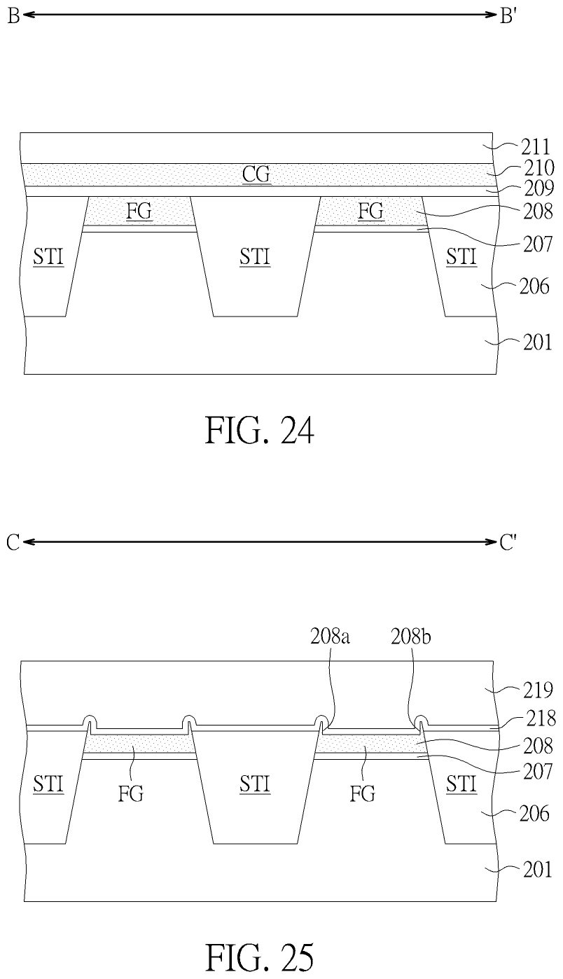

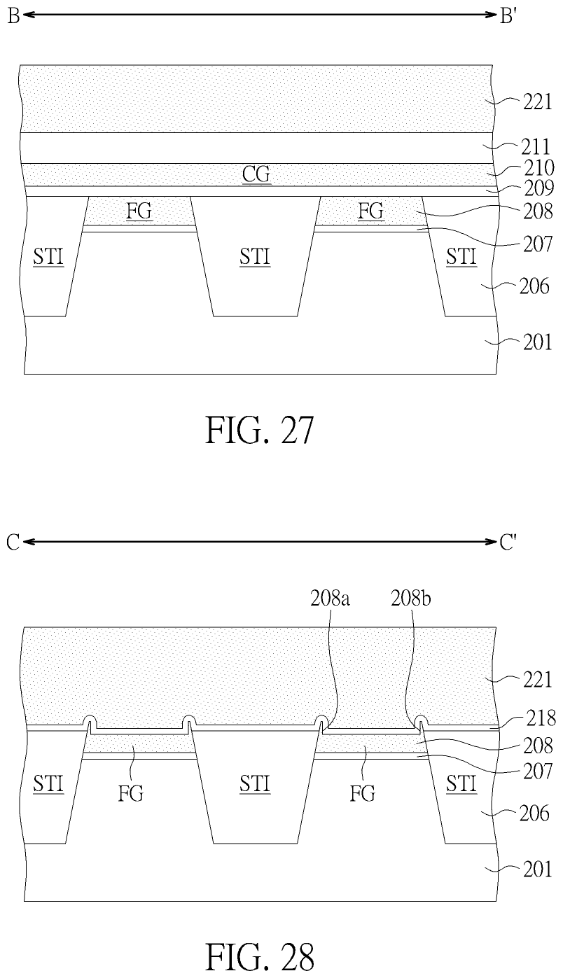

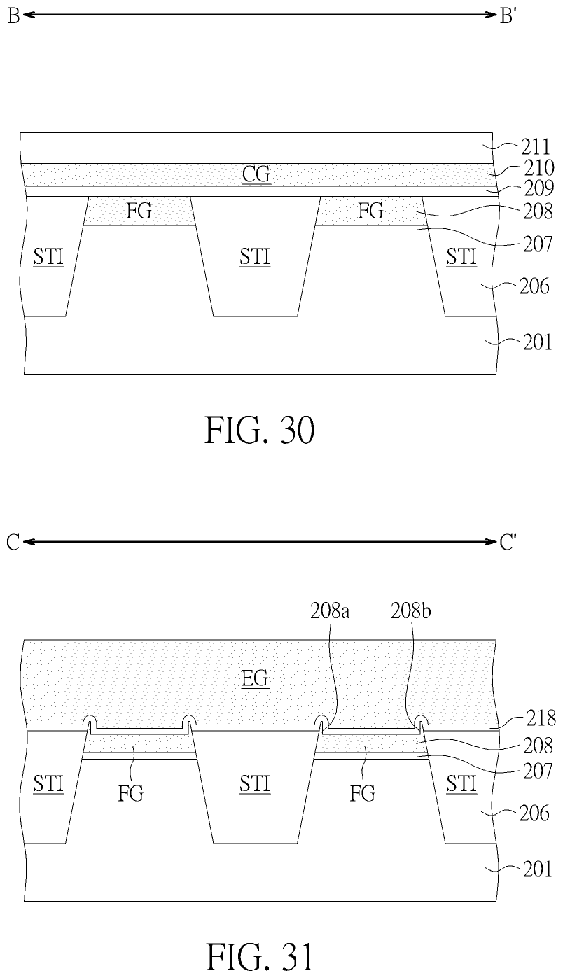

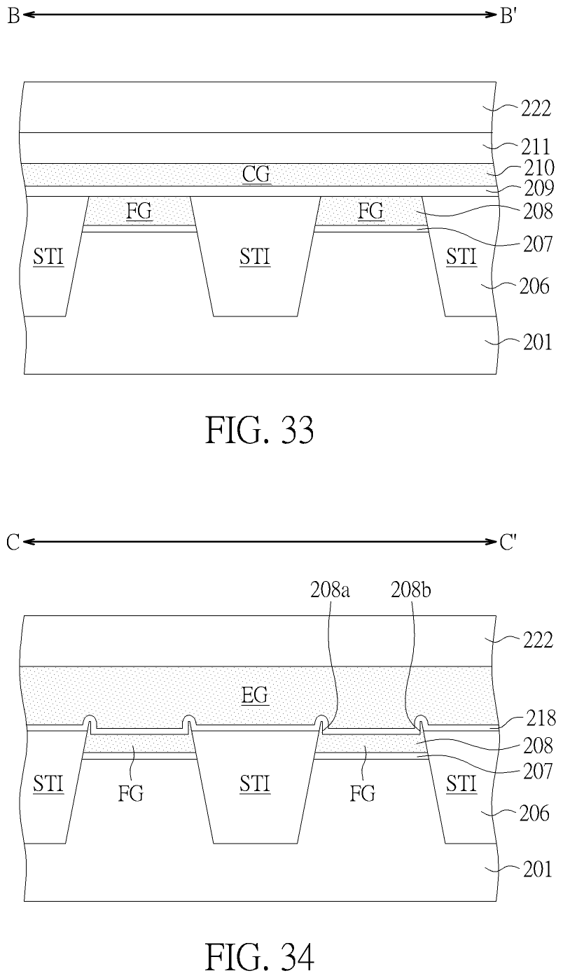

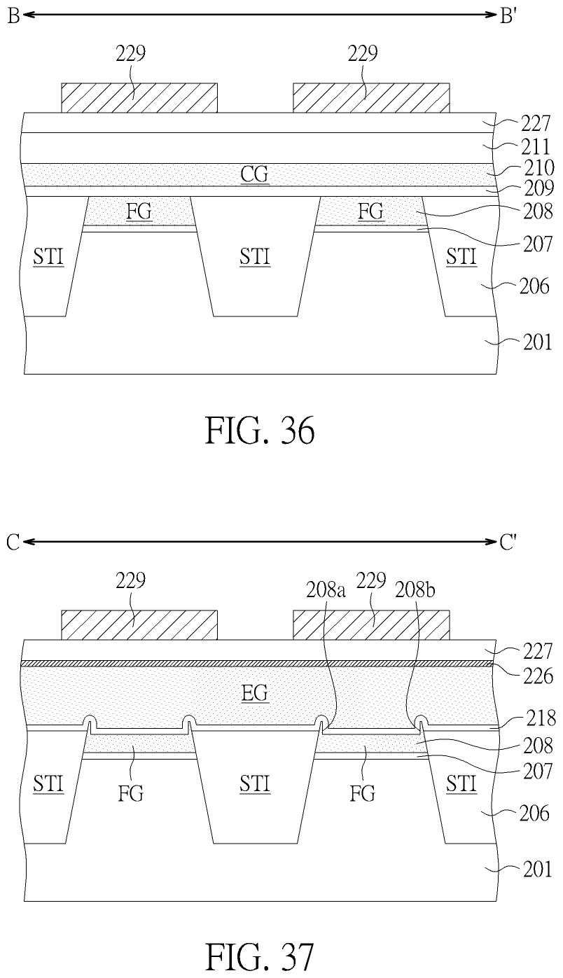

FIG. 5 to FIG. 37 are schematic, cross-sectional diagrams after each corresponding step in a manufacturing method for a non-volatile memory in this embodiment.

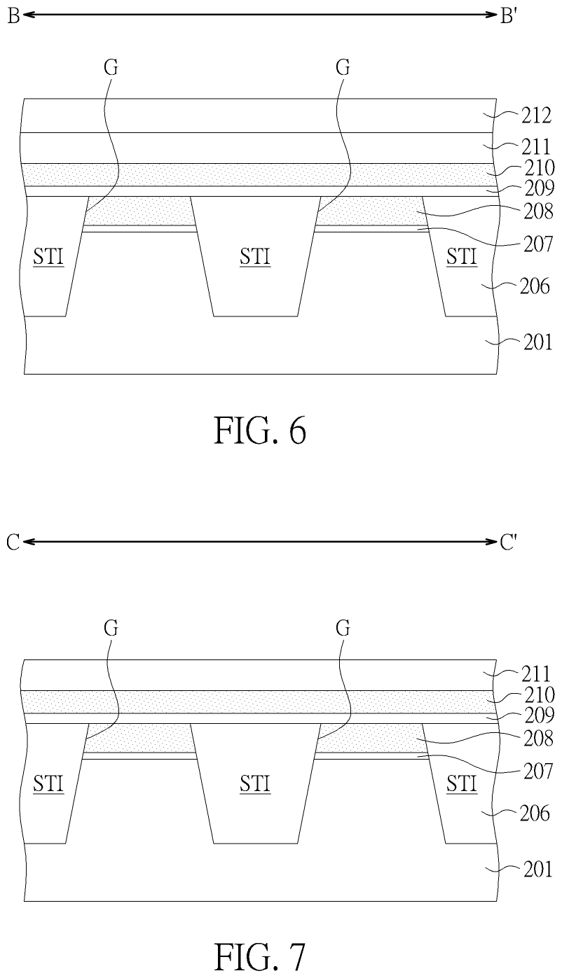

As shown in FIG. 5 to FIG. 7, a substrate 201 is provided, wherein the substrate 201 may be a P-type doped semiconductor substrate. In some embodiments, the substrate 201 may be a triple-well structure. For example, the substrate 201 may comprise a deep N well, and a P well may be formed in the deep N well. As shown in FIG. 6 and FIG. 7, grooves G are disposed on the substrate 201 and surrounded by the STI structure 206. A first gate dielectric layer 207 and a first conductive layer 208 are formed in sequence from bottom to top in the grooves G, and the first conductive layer 208 is planarized until being leveled with the top surface of the STI structure 206.

The first gate dielectric layer 207 may have a thickness ranging from 5 nm to 15 nm, for example, 6-12 nm. The first gate dielectric layer 207 may be a silicon oxide layer, a silicon oxynitride layer, or a hafnium oxide layer, but is not limited thereto. The first conductive layer 208 may be an N-type polysilicon layer, but is not limited thereto. The first conductive layer 208 may have a thickness ranging from 50 nm to 150 nm.

A second gate dielectric (or inter-poly dielectric) layer 209, a second conductive layer 210 and a protection dielectric layer 211 are deposited in sequence from bottom to top. A patterned photoresist layer 212 is then formed on the protection dielectric layer 211 to define control gate (CG) regions. The second gate dielectric layer 209 may be an oxide layer, a nitride layer, or an oxide-nitride-oxide (ONO) structure, wherein the ONO structure includes a first oxide layer with a thickness of 3 nm to 8 nm, a nitride layer with a thickness of 4 nm to 10 nm, and a second oxide layer with a thickness of 3 nm to 8 nm, but is not limited thereto. The second conductive layer 210 may have a thickness ranging from 80 nm to 250 nm, the material thereof may be N-type doped polysilicon, but is not limited to. The protection dielectric layer 211 may have a thickness ranging from 50 nm to 300 nm, wherein the protection dielectric layer 211 may comprise oxide, nitride, or a combination thereof.

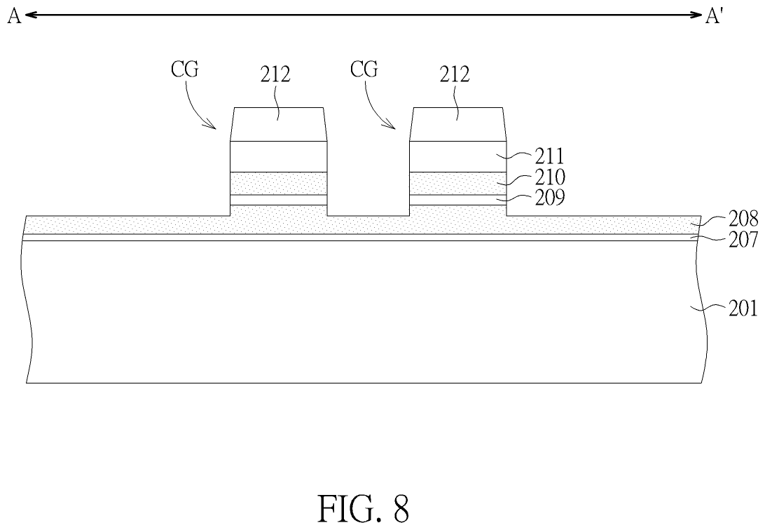

Subsequently, as shown in FIG. 8 to FIG. 10, using the patterned photoresist layer 212 as an etching mask, an anisotropic etching process is performed to etch the protection dielectric layer 211, the second conductive layer 210, and the second gate dielectric layer 209, until the first conductive layer 208 is exposed, thereby forming control gates CG on the first conductive layer 208. As shown in FIGS. 8 and 10, the etching process continues in the regions not covered by the patterned photoresist layer 212 to recess the first conductive layer 208, thereby forming a first sharp portion 208a and a second sharp portion 208b at the opposite corners, wherein the two sharp portions are attached to two opposite sidewalls of the STI structure 206, respectively.

Further, a removed part of the first conductive layer 208 may have a thickness ranging from 20 nm to 100 nm. The first sharp portion 208a and the second sharp portion 208b may have a height h ranging from 20 nm to 100 nm.

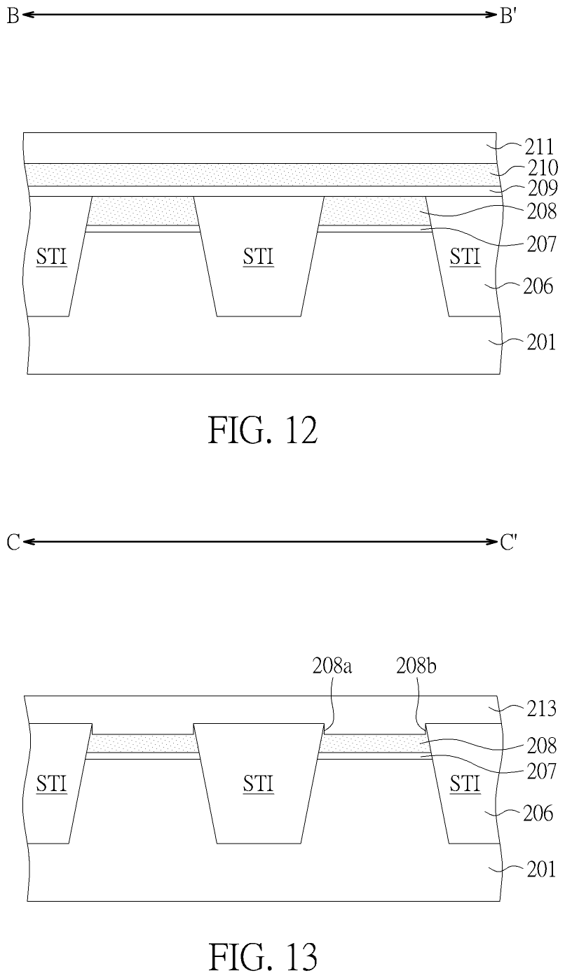

As shown in FIG. e to FIG. 13, after removing the patterned photoresist layer 212, a patterned photoresist layer 213 is formed to cover the first conductive layer 208 above a source region S. At this point, the first sharp portion 208a and the second sharp portion 208b are protected by the patterned photoresist layer 213. An anisotropic etching is then performed to remove a part of the first conductive layer 208 which is not covered by the patterned photoresist layer 213 and the control gates CG.

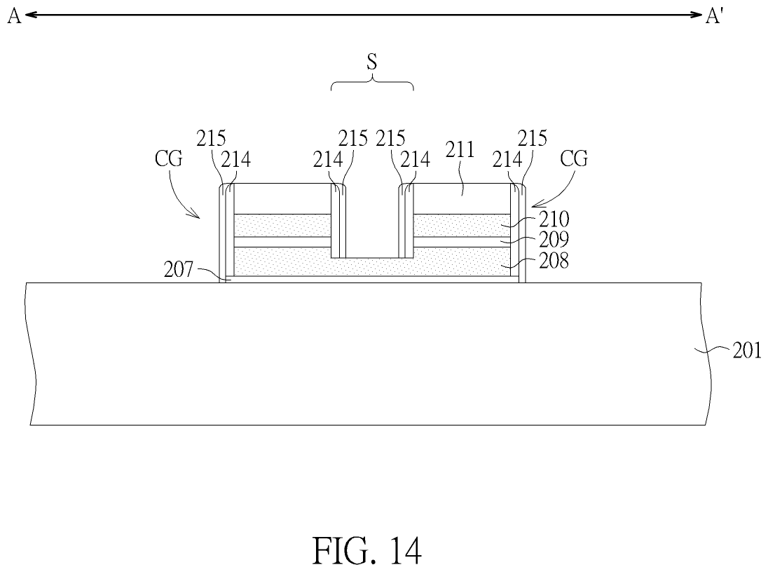

As shown in FIG. 14 to FIG. 16, after removing the patterned photoresist layer 213, a first spacer 214 is formed on each side of the control gate CG. The first gate dielectric layer 207 which is not covered by the first conductive layer 208 and the first spacer 214 may be removed. The first spacer 214 may comprise silicon oxide, silicon nitride, or a combination thereof. After forming the first spacer 214, a second spacer 215 may be formed on the first spacer 214, wherein the first spacer 214 and the second spacer 215 may have different compositions. The second spacer 215 may comprise silicon oxide.

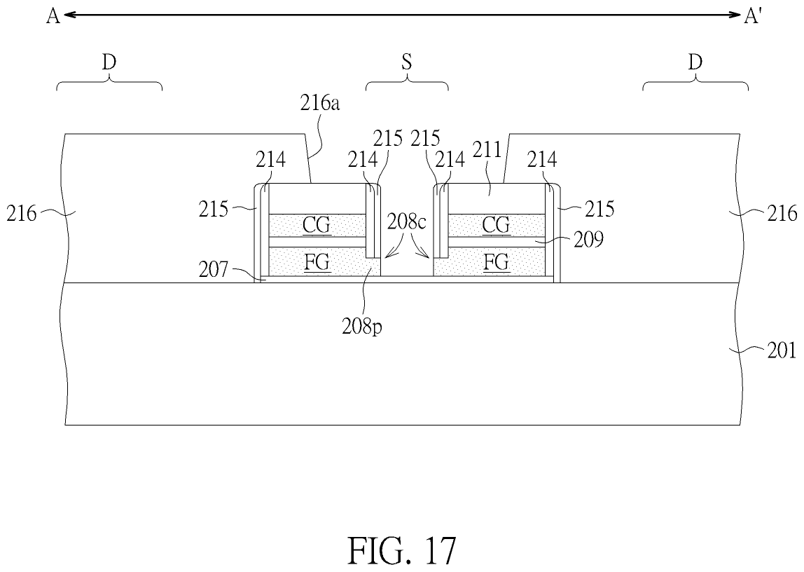

As shown in FIG. 17 to FIG. 19, a patterned photoresist layer 216 is formed. The patterned photoresist layer 216 covers the drain regions D. The patterned photoresist layer 216 has an opening 216a that exposes the source region S. An anisotropic etching process is then performed to remove a part of the first conductive layer 208 not covered by the control gates CG, the first spacer 214 and the second spacer 215, thereby forming floating gates FG. The control gate CG partially overlaps with the underlying floating gate FG. A lower portion 208p of the floating gate FG inwardly protrudes beyond a sidewall of the control gate CG. An upper corner 208c of the lower portion 208p, which is formed by one side surface of the floating gate FG and a part of a top surface of the floating gate FG, is not covered by the control gate CG. The corner 208c is connected between the first sharp portion 208a and the second sharp portion 208b.

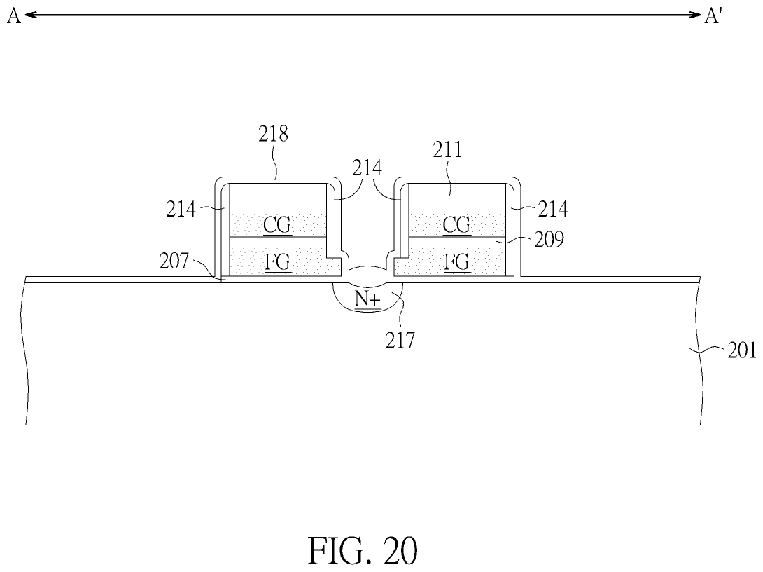

Subsequently, as shown in FIG. 20 to FIG. 22, an ion implantation process is performed to implant N-type dopants into the source region S. The N-type dopants may be a combination of phosphorus and arsenic ions, but is not limited thereto. The implanted dopants may have implant energy ranging from 10 KeV to 30 KeV and dosage ranging from 8E14/cm² to 5E15/cm². The patterned photoresist layer 216 is removed. The second spacer 215 is then removed by wet etching. A part of the STI structure 206, with a thickness of 20 nm to 80 nm, is removed to expose the tips of the first sharp portion 208a and the second sharp portion 208b. A rapid thermal annealing (RTA) or furnace annealing is then performed to repair damage and activate dopants to form a heavily doped source region 217. It should be noted that, the annealing here can be omitted if a heat cycle step in a subsequent process can achieve repairing damage and driving in dopants.

Subsequently, a tunneling dielectric layer 218 is deposited in a blanket manner. The tunneling dielectric layer 218 conformally covers the surface of the substrate 201 and structures on the substrate 201. The tunneling dielectric layer 218 may have a thickness ranging from 8 nm to 16 nm, and a material thereof may be silicon oxide or silicon oxynitride. The tunneling dielectric layer 218 is preferably made of a combination of a deposited oxide and a thermal oxide, for example, including both a high temperature oxide (HTO) and a thermal oxide, and is annealed by using NO or N₂O. During thermal oxidation circulation, due to high concentration of N-type doping ions, a part of the tunneling dielectric layer 218 located above the source region S becomes thicker, and is thicker than the first gate dielectric layer 207.

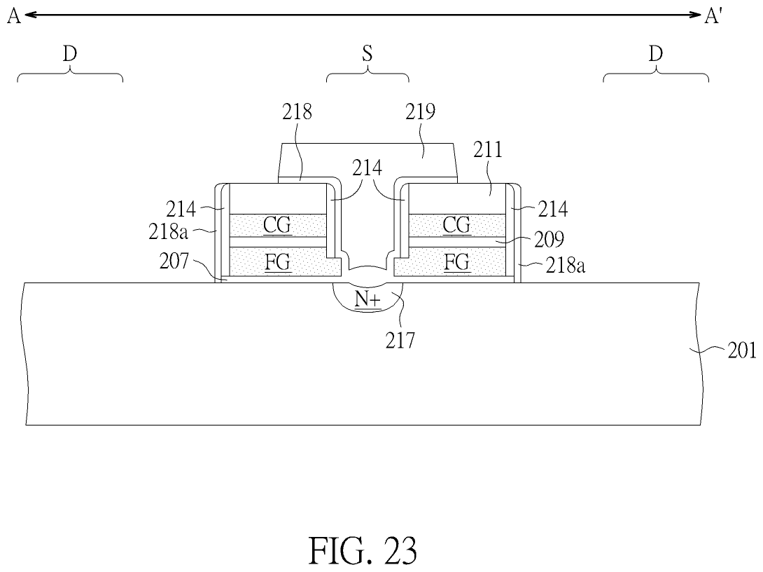

As shown in FIG. 23 to FIG. 25, a part of the tunneling dielectric layer 218 is removed, and the part of the tunneling dielectric layer 218 which is located above the source region S is reserved.

Specifically, a patterned photoresist layer 219 is formed first to cover the source region S, but expose the drain regions D. An etching process, preferred to be a combination of anisotropic dry etching and isotropic wet etching, is then performed to etch the exposed tunneling dielectric layer 218, thereby forming opposite third spacers 218a on the first spacers 214. The third spacer 218a is located on a side of the floating gate FG which is away from the source region S, and covers an external side surface of the first spacer 214. The patterned photoresist layer 219 is then removed.

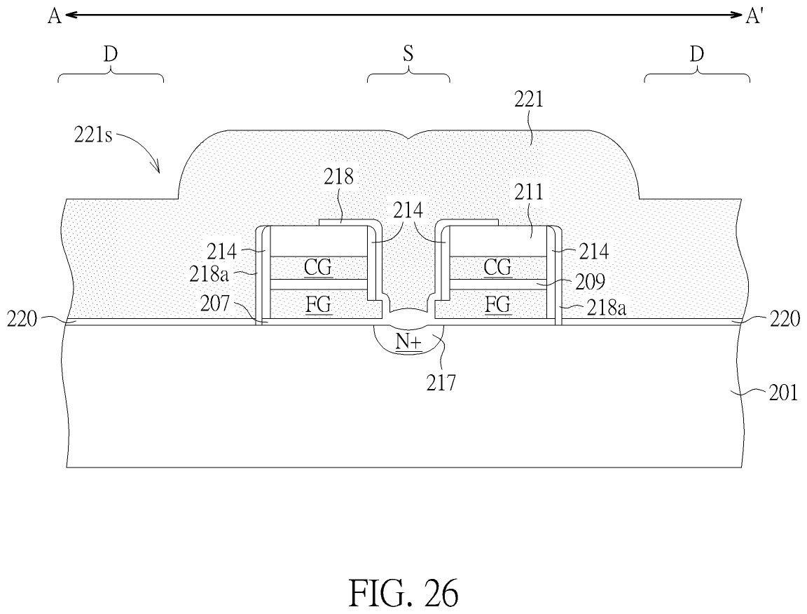

As shown in FIG. 26 to FIG. 28, after removing the patterned photoresist layer 219, a third gate dielectric layer 220 is formed on the surface of the substrate 201. The third gate dielectric layer 220 may have a thickness ranging from 2 nm to 10 nm, and the material thereof may be an oxide such as silicon dioxide, or may be an oxynitride such as silicon oxynitride. This step can also anneal the tunneling dielectric and enhances its quality. A third conductive layer 221 is formed on the surfaces of the third gate dielectric layer 220 and the tunneling dielectric layer 218. The material of the third conductive layer 221 may be N-type doped polysilicon. The third conductive layer 221 covers the surfaces of structures on the substrate 201 and forms a step 221s.

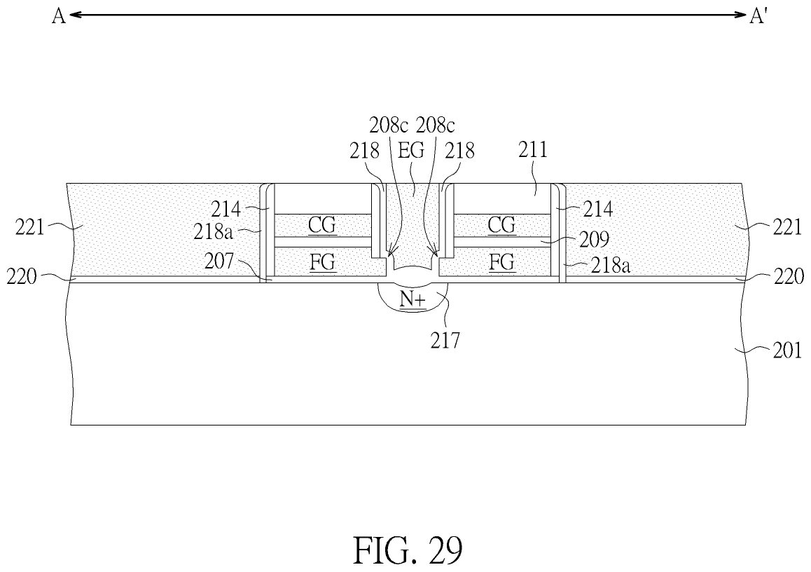

As shown in FIG. 29 to FIG. 31, The third conductive layer 221 is planarized by means of, for example, chemical mechanical polishing (CMP). It is noted that the tunneling dielectric layer 218 on the protection dielectric layer 211 could be completely removed, partially removed, or intact, depending upon CMP planarization process. After the planarization, a part of the third conductive layer 221 which is located above the source region S is used as an erase gate EG. The tunneling dielectric layer 218 and the erase gate EG above the tunneling dielectric layer 218 jointly form an erase gate structure. The erase gate structure is located on a side, which is provided with the corner 208c, of the floating gate FG. The tunneling dielectric layer 218 conformally covers the first sharp portion 208a, the second sharp portion 208b, and the tip of the corner 208c.

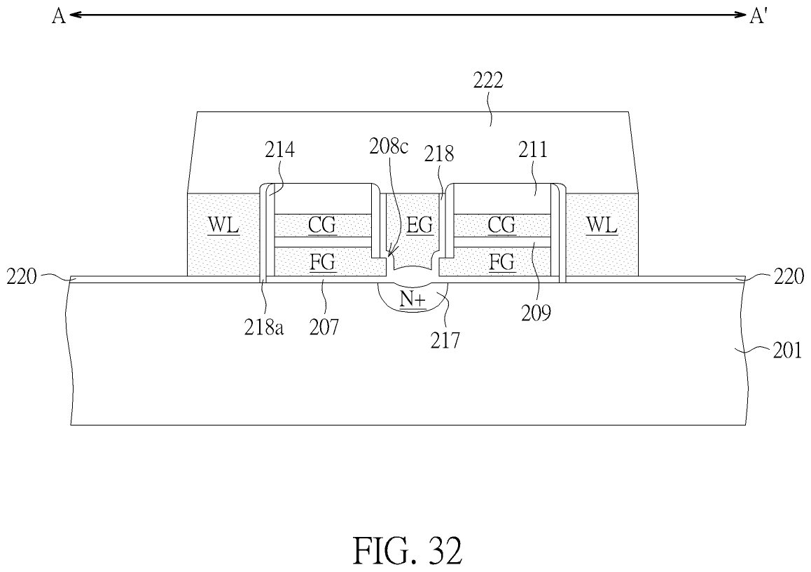

As shown in FIG. 32 to FIG. 34, a patterned photoresist layer 222 is formed to define a word line region. The patterned photoresist layer 222 covers the erase gate EG. Using the patterned photoresist layer 222 as a mask, an anisotropic etching process is then performed to etch the third conductive layer 221. The uncovered part of the third conductive layer 211 is removed. An un-etched part of the third conductive layer 221 which is located on a side of the floating gate FG away from the corner 208c is reserved as a word line WL. The word line WL and the third gate dielectric layer 220 under the word line WL jointly form a word line structure.

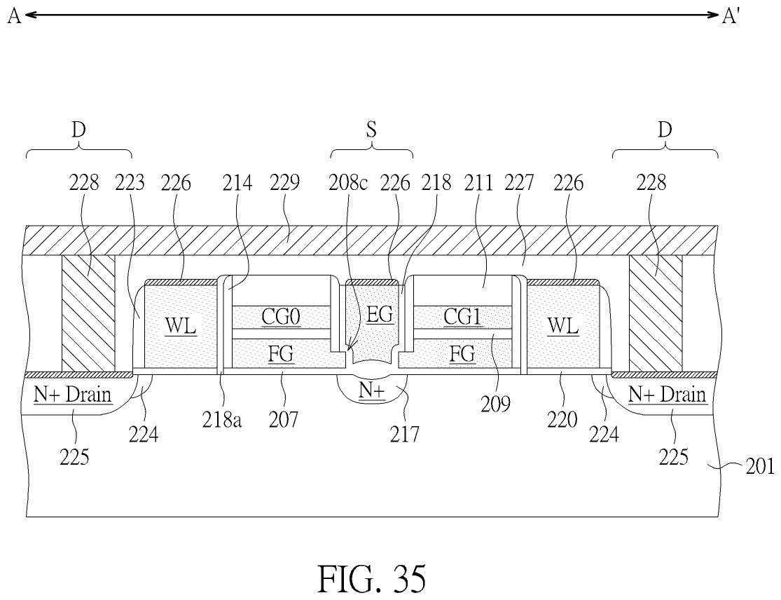

As shown in FIG. 35 to FIG. 37, a back end process in standard integrated circuit manufacturing is performed to form at least one lightly doped drain region 224 in the substrate 201, at least one fourth spacer 223 on a sidewall of the word line WL, at least one heavily doped drain 225 in the substrate 201, a silicide layer 226 (self-aligned silicide) on the drain region D, on the erase gate EG, and on the word lines WL. An interlayer dielectric layer 227 is deposited in a blanket manner, and at least one contact 228 is formed in the interlayer dielectric layer 227. At least one metal bit line 229 is formed on the interlayer dielectric layer 227. The lightly doped drain 224 and the heavily doped drain region 225 are disposed within the drain region D. The drain region D is formed in the substrate 201, located on a side of the word line WL which is away from the floating gate FG, and partially overlaps the word line WL.

Specifically, the at least one lightly doped drain region 224 is formed in the substrate 201 first. The fourth spacer 223 is then formed, where the fourth spacer 223 is located on a side of the word line WL which is away from the floating gate FG. Next, the heavily doped drain 225 is formed in the substrate 201 by using ion implantation processes known in the art. The silicide layer 226 is then formed on the surface of the drain region D, the surface of the word line WL and the surface of the erase gate EG. The interlayer dielectric layer 227 is then formed on the substrate 201. The interlayer dielectric layer 227 covers structures on the substrate 201. The at least one contact 228 is then formed in the interlayer dielectric layer 227. The at least one metal bit line 229 is formed on the interlayer dielectric layer 227. The contact 228 is connected to the metal bit line 229 and the heavily doped drain 225.

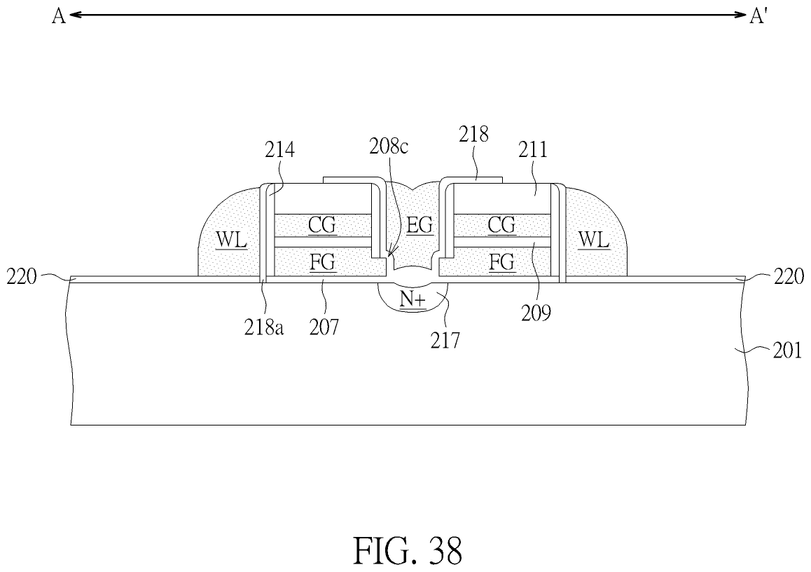

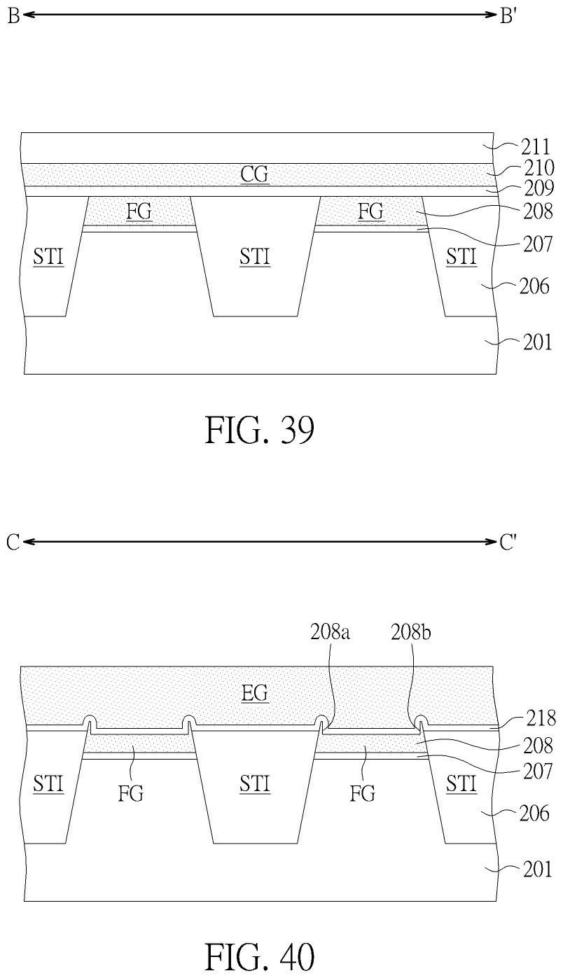

In a variant embodiment, hereby some components described in the same way as in previous embodiment will not be repeated. The word line structure may be formed on the substrate 201 by using another approach. Referring to FIG. 38 to FIG. 40, after the patterned photoresist layer 219 is removed (as depicted in FIG. 23), a third gate dielectric layer 220 with a thickness ranging from 2 nm to 10 nm is formed on the surface of the substrate 201, and a third conductive layer 221 (as depicted in FIG. 26) with a thickness ranging from 100 nm to 450 nm is deposited. The third conductive layer 221 covers the surfaces of structures on the substrate 201 and forms a step 221s. Herein, the prior steps in this embodiment are the same as those shown in FIGS. 23 to 26 and will not be repeated for the sake of simplicity. An anisotropic etching process is then performed to the third conductive layer 221 to remove a part of the third conductive layer 221, until the gate dielectric layer 220 and the protection dielectric layer 211 are exposed.

A part of the third conductive layer 221 which is located above the source region S is reserved as an erase gate EG, and a part of the third conductive layer 221 which is on a side of the floating gate FG away from the corner 208c is reserved as a word line WL. The erase gate EG and the tunneling dielectric layer 218 under the erase gate EG jointly form an erase gate structure; the word line WL and the third gate dielectric layer 220 under the word line WL jointly form a word line structure.

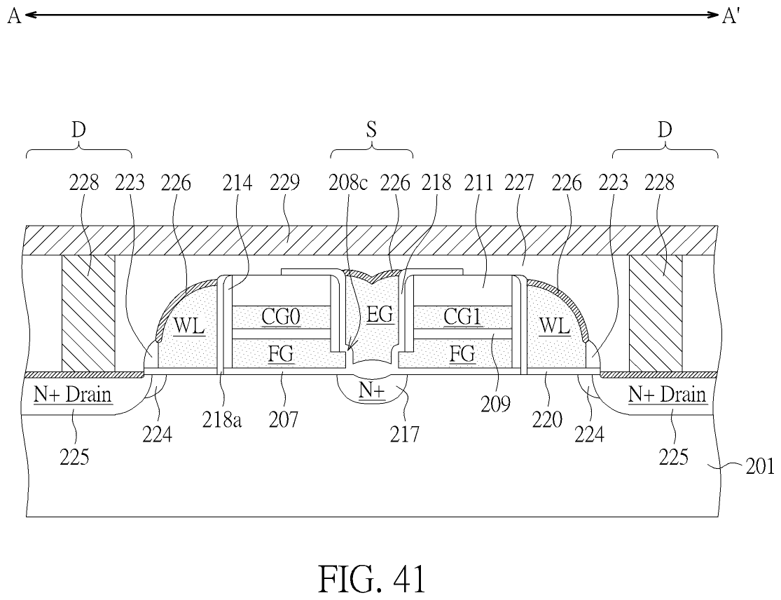

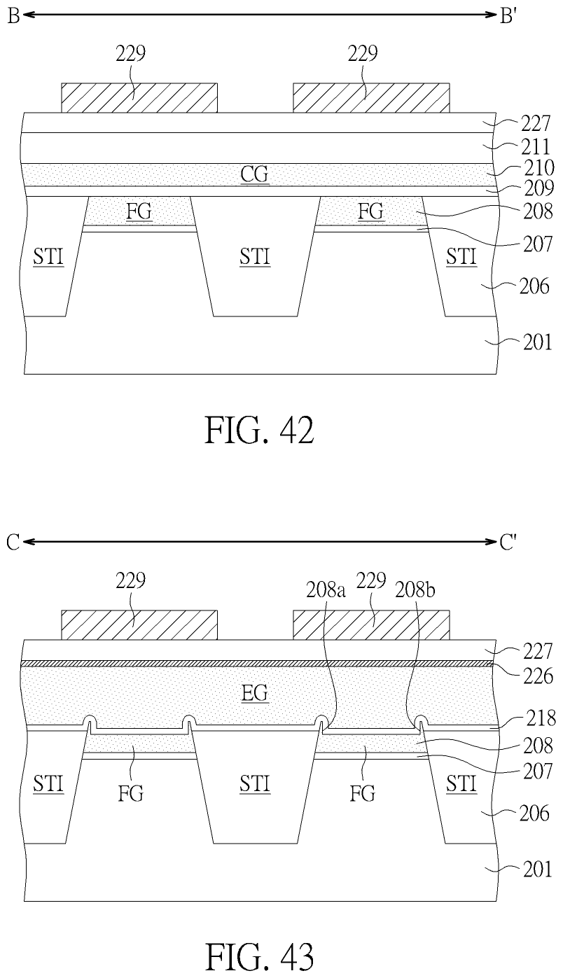

Referring to FIG. 41 to FIG. 43, a back end process in standard integrated circuit manufacturing is performed to form at least one lightly doped drain 224, at least one fourth spacer 223, at least one heavily doped drain 225, a silicide layer 226 (self-aligned silicide), an interlayer dielectric layer 227, at least one contact 228 and at least one metal bit line 229. The lightly doped drain 224 and the heavily doped drain 225 are disposed within the drain region D. It is noteworthy that, in this embodiment, the height of the fourth spacer 223 is lower than the word line WL. The drain region D is formed in the substrate 201, located on a side of the word line structure which is away from the floating gate structure, and partially overlaps the word line structure.

In view of the above, a non-volatile memory is manufactured. The floating gate FG has a first sharp portion 208a and a second sharp portion 208b, which are disposed adjacent to two opposite sidewalls of the shallow trench isolation structure 206 respectively, and tips of the first sharp portion 208a and the second sharp portion 208b are higher than the top surface of the shallow trench isolation structure 206. The control gate structure, which is located on the floating gate structure, covers a partial area of the floating gate structure, and comprises the second gate dielectric layer 209 and the control gate CG. A corner 208c composed of one side surface of the floating gate structure and a part of a top surface of the floating gate structure is not covered by the control gate structure, and the corner 208c is connected between the first sharp portion 208a and one end of the second sharp portion 208b. The erase gate structure is located on the substrate 201 and on a side, which is provided with the corner 208c.

In addition, the first and second sharp portions at the opposite edges of the floating gate FG may cause electron tunneling through the tunneling dielectric layer 218 from the floating gate FG to the erase gate EG during programming when a high voltage is applied to the control gate CG. Since the floating gate FG does not have such sharp portions directly under the control gate CG, the program disturb issue can be avoided or mitigated.

The first sharp portion 208a and the second sharp portion 208b have a height ranging from 20 nm to 100 nm. The tunneling dielectric layer 218, which is located above the source region S, has a thickness greater than that of the first gate dielectric layer 207 and that of the rest of the tunneling dielectric layer 218 that is not located directly above the source region S. This can prevent tunneling or even dielectric breakdown between erase gate EG and the source region during erase operation. The non-volatile memory further has a protection dielectric layer 211 formed on the control gate structure, and the tunneling dielectric layer 218 further covers a part of the protection dielectric layer 211. The non-volatile memory further has at least one sidewall structure. The sidewall structure is disposed between the control gate structure and the erase gate structure, between the floating gate structure and the word line structure, between the control gate structure and the word line structure, and on a side of the word line structure which is away from the floating gate structure.

The non-volatile memory further comprises a silicide layer 226, an interlayer dielectric layer 227, at least one metal bit line 229, and at least one contact 228. The silicide layer 226 is located on the surface of the drain region D, on the surface of the word line WL, and on the surface of the erase gate EG. The interlayer dielectric layer 227 is located on the substrate 201 and covers structures on the substrate 201. The metal bit line 229 is located on the interlayer dielectric layer. The contact 228 is located in the interlayer dielectric layer 227. A top end of the contact 228 is connected to the metal bit line 229, and a bottom end of the contact 228 is connected to the drain region D.

The substrate 201 is a P-type substrate, and correspondingly, the source area, the drain area, the first conductive layer, the second conductive layer, the erase gate and the word line are all N-type doped. In some embodiments, the substrate is an N-type substrate, and correspondingly, the source area, the drain area, the first conductive layer, the second conductive layer, the erase gate and the word line are all P-type doped. The first gate dielectric layer 207 has a thickness ranging from 5-15 nm, the second gate dielectric layer 209 has a thickness ranging from 10-22 nm, the tunneling dielectric layer 218 has a thickness ranging from 8-15 nm, and the third gate dielectric layer 220 has a thickness ranging from 2-8 nm. Materials of the first conductive layer, the second conductive layer, the erase gate and the word line may all comprise doped polysilicon.

The non-volatile memory according to the present invention can be programmed based on a suitable bias condition. Table 1 lists an example of programming bias condition of the memory transistor.

Program Condition

| Terminal | Bias Voltage | |
|---|---|---|
| Selected WL | 0.5-1.8 | V |
| Unselected WL | (−2)-0 | V |
| Selected CG | 8-14 | V |
| Unselect CG | 0 | V |
| Source Line | 3-6 | V |
| Selected BL | 0-1 | V |
| All EG | 0 | V |
| Unselected BL | 1.2-3.5 | V |
| Substrate | 0 | V |

The non-volatile memory according to the present invention can be erased based on a suitable bias condition. Table 2 lists an example of erase bias condition of the memory transistor.

Erase Condition

| Terminal | Bias Voltage | |
|---|---|---|
| Selected WL | (−3)-0 | V |
| Unselected WL | 0 | V |
| Selected CG | (−5)-0 | V |
| Unselected CG | 0 V or Floating | |
| Selected EG | 5-12 | V |
| Unselected EG | 0 V or Floating | |
| Source Line | 0 V or Floating | |
| All BL | 0 V or Floating | |
| Substrate | 0 | V |

The non-volatile memory according to the present invention can be read based on a suitable bias condition. Table 1 lists an example of read bias condition of a memory transistor.

Read Condition

| Terminal | Bias Voltage | |
|---|---|---|
| Selected WL | 1.2-3.6 | |
| Unselected WL | 0 | V |
| All or selected CG | 0-3.6 | V |
| Source Line | 0 | V |
| Selected BL | 0.8-2.5 | V |
| Unselected BL | 0 V or Floating | |
| Substrate | 0 | V |

In conclusion, in the non-volatile memory according to the present invention, the floating gate structure has a first sharp portion and a second sharp portion, and the corner composed of a side surface of the floating gate structure and a part of a top surface of the floating gate structure is not covered by a control gate structure, wherein the first sharp portion and the second sharp portion are only disposed on the part of the top surface of the floating gate structure not covered by the control gate structure. The corner is connected between the first sharp portion and one end of the second sharp portion. A tunneling dielectric layer of the erase gate structure covers the first sharp portion, the second sharp portion, and a tip part of the corner. During an erase operation, electrons are injected into the erase gate structure from the first sharp portion, the second sharp portion and the tip of the corner of the floating gate structure in an FN tunneling manner, thereby effectively enhancing an FN tunneling effect between the floating gate and the erase gate, and improving erase efficiency. The sharp portions of the floating gate as well as the corner not covered by the control gate structure helps increase the thickness of the tunneling dielectric layer between the erase gate and the floating gate, thereby preventing current leakage and helping improve data retention. In the manufacturing method for a non-volatile memory according to the present invention, the floating gate structure having the first sharp portion and the second sharp portion is formed skillfully, and the process is simple and practical. Therefore, the present invention effectively overcomes various disadvantages in the prior art and hence has high industrial use value.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A non-volatile memory, comprising:
a substrate;
at least one shallow trench isolation structure, wherein a top surface of the shallow trench isolation structure is higher than a top surface of the substrate, and a lower portion of the shallow trench isolation structure is embedded in the substrate to define a plurality of active areas in the substrate;
at least one floating gate structure, located on the substrate and comprising a first gate dielectric layer and a floating gate, wherein the floating gate has a first sharp portion and a second sharp portion, the first sharp portion and the second sharp portion are attached to two opposite sidewalls of the shallow trench isolation structure respectively, and wherein tips of the first sharp portion and the second sharp portion are higher than a top surface of the shallow trench isolation structure;
at least one control gate structure, located on the floating gate structure, covering a partial area of the floating gate structure, and comprising a second gate dielectric layer and a control gate, wherein a corner is formed by one side surface of the floating gate structure and a part of a top surface of the floating gate structure is not covered by the control gate structure, the corner is connected between the first sharp portion and one end of the second sharp portion, wherein the first sharp portion and the second sharp portion are only disposed on the part of the top surface of the floating gate structure not covered by the control gate structure;
at least one erase gate structure located on the substrate, wherein the erase gate structure is located on a side, which is provided with the corner, of the floating gate structure and comprises a tunneling dielectric layer and an erase gate, the tunneling dielectric layer covers the first sharp portion, the second sharp portion and a tip of the corner; and
at least one word line structure, located on the substrate, wherein the word line structure is located on a side, which is away from the corner, of the floating gate structure and comprises a third gate dielectric layer and a word line.

2. The non-volatile memory according to claim 1, wherein the first sharp portion has a height ranging from 20 nm to 100 nm, and the second sharp portion has a height ranging from 20 nm to 100 nm.

3. The non-volatile memory according to claim 1, wherein a part of the tunneling dielectric layer, which is located above the source region, has a thickness greater than that of the first gate dielectric layer and that of rest of the tunneling dielectric layer that is not located directly above the source region.

4. The non-volatile memory according to claim 1 further comprising:
a protection dielectric layer on the control gate structure.

5. The non-volatile memory according to claim 1 further comprising:
at least one sidewall structure, the sidewall structure is disposed between the control gate structure and the erase gate structure, between the floating gate structure and the word line structure, between the control gate structure and the word line structure, and on a side of the word line structure which is away from the floating gate structure.

6. The non-volatile memory according to claim 1 further comprising:
at least one source region and at least one drain region, the source region and the drain region are located in the substrate, the source region is located under the erase gate structure and partially overlaps the floating gate structure, and the drain region is located on a side of the word line structure which is away from the floating gate structure, and partially overlaps the word line structure.

7. The non-volatile memory according to claim 1, wherein further comprising:
a silicide layer, an interlayer dielectric layer, at least one metal bit line, and at least one contact, wherein the silicide layer is located on the drain region, the word line, and the erase gate, wherein the interlayer dielectric layer is located on the substrate and covers structures on the substrate, wherein the metal bit line is located on the interlayer dielectric layer, wherein the contact is located in the interlayer dielectric layer, and wherein the contact is connected to the metal bit line and the drain region.

8. The non-volatile memory according to claim 1, wherein the top surface of the floating gate structure comprises a flat surface and a recessed surface, wherein the flat surface is directly under the control gate, and the recessed surface is directly under the erase gate, wherein the recessed surface of the floating gate is lower than the flat surface of the floating gate, and wherein the first and second sharp portions protrude from the recessed surface of the floating gate directly under the erase gate and from the recessed surface of the shallow trench isolation structure adjacent to the first and second sharp portions.

9. The non-volatile memory according to claim 1, wherein the first gate dielectric layer has a thickness ranging from 5 nm to 15 nm, the second gate dielectric layer has a thickness ranging from 10 nm to 22 nm, the tunneling dielectric layer has a thickness ranging from 8 nm to 15 nm, and the third gate dielectric layer has a thickness ranging from 2 nm to 8 nm.

10. A method for fabricating a non-volatile memory, comprising:
providing a substrate;
forming at least one shallow trench isolation structure, wherein a top surface of the shallow trench isolation structure is higher than a top surface of the substrate, and a lower portion of the shallow trench isolation structure is embedded in the substrate to define a plurality of active areas in the substrate;
forming at least one floating gate structure on the substrate, the at least one floating gate structure comprising a first gate dielectric layer and a floating gate, wherein the floating gate has a first sharp portion and a second sharp portion, the first sharp portion and the second sharp portion are attached to two opposite sidewalls of the shallow trench isolation structure respectively, and wherein tips of the first sharp portion and the second sharp portion are higher than a top surface of the shallow trench isolation structure;
forming at least one control gate structure on the floating gate structure, covering a partial area of the floating gate structure, the at least one control gate structure comprising a second gate dielectric layer and a control gate, wherein a corner is formed by one side surface of the floating gate structure and a part of a top surface of the floating gate structure is not covered by the control gate structure, the corner is connected between the first sharp portion and one end of the second sharp portion, wherein the first sharp portion and the second sharp portion are only disposed on the part of the top surface of the floating gate structure not covered by the control gate structure;
forming at least one erase gate structure on the substrate, wherein the erase gate structure is located on a side, which is provided with the corner, of the floating gate structure and comprises a tunneling dielectric layer and an erase gate, the tunneling dielectric layer covers the first sharp portion, the second sharp portion and a tip of the corner; and
forming at least one word line structure, located on the substrate, wherein the word line structure is located on a side, which is away from the corner, of the floating gate structure and comprises a third gate dielectric layer and a word line.
